(19) United States
(12) Patent Application Publication
(10) Pub. No.: US 2026/0260836 A1
(43) Pub. Date: Sep. 3, 2026

(54) ELECTRON BEAM EMISSION STRUCTURE AND FIELD EMISSION DEVICE

(71) Applicant: Meidensha Corporation, Tokyo (JP)

(72) Inventor: Takumi HAYASHI, Tokyo (JP)

(73) Assignee: Meidensha Corporation, Tokyo (JP)

(21) Appl. No.: 19/164,606

(22) PCT Filed: Mar. 8, 2024
(86) PCT No.: PCT/JP2024/009057

§ 371 Date: Sep. 12, 2025

(30) Foreign Application Priority Data
Mar. 15, 2023 (JP) 2023-040328

(51) Int. Cl. H01J 35/06

(52) U.S. Cl. CPC H01J 35/045; H01J 35/064; H01J 35/065; H01J 35/066; H01J 35/08; H01J 35/14; H01J 35/147; H01J 35/153; H01J 35/30

(57) ABSTRACT

An electron beam emission structure is provided with an electron source and a guard electrode. The electron source emits an electron beam to a target of a field emission device. The guard electrode is disposed around the electron source. In the electron source, the end surface facing the target constitutes an electron emission surface. The electron emission surface has a center part forming a curved concave surface and a peripheral edge portion forming a curved convex surface.

### TECHNICAL FIELD

The present invention relates to a structure of an electron source for small focalization of a cold cathode-type field emission device.

### BACKGROUND TECHNOLOGY

In cold cathode-type X-ray tubes, in addition to low power consumption, the size can be reduced, response speed is fast, and electron density is high. Therefore they are superior to hot cathode types. Then, in such X-ray tubes, various measures have been taken to reduce the focus size, such as miniaturizing the electron source, installing a focusing tube, and angling a target (patent document 1).

### PRIOR ART DOCUMENT(S)

### Patent Document(s)

Patent document 1: Japanese Patent Application Publication No. 2010-56062

### SUMMARY OF THE INVENTION

In a conventional field emission device such as that described in the patent document 1, an electron beam is focused by the electric field generated by the shape of the electron emission surface of the electron source and the guard electrode. However, in the configuration of the conventional technology, there is a limit to the focusing of the electron beam.

In an electron source 2 having an electron emission surface 20 forming a curved concave surface as shown in FIG. 6(a), when equipped with a guard electrode 3 shown in FIG. 6(b), an electron beam B exhibits different characteristics between the center part and the peripheral edge portion of the electron emission surface 20 of the electron source 2, as shown below.

The center part of the electron emission surface 20 is perpendicular to the traveling direction of the electron beam B, and the electron beam B is emitted parallel to the traveling direction, and thereby the electron beam B travels in a straight line without being easily affected by the electric field of the guard electrode 3. The peripheral edge portion of the electron emission surface 20 is slightly angled with respect to the traveling direction of the electron beam B, and the electron beam B is emitted toward a center axis a and is affected by the electric field of the guard electrode 3, causing it to be focused by two combined forces in the direction of the center axis a of the electron source 2.

When attempting to focus the electron beam B emitted from the center part of the electron emission surface 20 on a surface of the target 4, the electron beam B emitted from the peripheral edge portion of the electron emission surface 20 crosses before reaching the target 4, as shown in FIG. 6(c). In addition, when attempting to focus the electron beam B emitted from the peripheral edge portion, the electron beam B emitted from the center part is not sufficiently focused and remains wide.

It has been known that discharge in a vacuum occurs not only at a point where the electric field reaches its peak but also at a point where the electric field is approximately 80% of the peak value. It is necessary to create a strong electric field peak at the guard electrode 3 to activate it, in order to protect the electron source 2. However, when creating a strong electric field peak at the guard electrode 3, the focusing ability of the electron beam B increases, and the cross point of the electron beam B is shifted toward the electron source 2, as a result of which the electron beam B becomes diffused near the target 4.

In view of the above problem, an object of the present invention is to achieve the emission of a high-intensity electron beam from a wide area of the electron emission surface and its small-focusing.

Therefore, the present invention, in one aspect thereof, is an electron beam emission structure including: an electron source for emitting an electron beam to a target; and a guard electrode disposed around the electron source, wherein an electron emission surface of the electron source for emitting the electron beam has a center part forming a curved concave surface and a peripheral edge portion forming a curved convex surface.

In one aspect of the present invention, in the electron beam emission structure, the guard electrode is provided with a covering portion that covers the peripheral edge portion.

In one aspect of the present invention, in the electron beam emission structure, the electron emission surface has a smooth surface at a boundary between the curved concave surface and the curved convex surface.

One aspect of the present invention is a field emission device having the electron beam emission structure.

According to the present invention, it is possible to emit a high-intensity electron beam from a wide area of the electron emission surface and to minimize the electron beam focus.

### BRIEF DESCRIPTION OF THE DRAWINGS

FIG. 1 is a cross-sectional view of an electron beam emission structure in an embodiment 1 of the present invention.

FIG. 2 is a cross-sectional view of the electron beam emission structure of the embodiment 1, showing the shape of an electron beam.

FIG. 3 is a cross-sectional view of the electron beam emission structure in an embodiment 2 of the present invention.

FIG. 4 is an electric field distribution diagram of the electron beam emission structure in the embodiment 2.

FIG. 5 is a cross-sectional view of the electron beam emission structure in an embodiment 3 of the present invention.

FIG. 6(a) is a cross-sectional view showing the focusing of an electron beam from a conventional electron source having a curved concave surface in the center part, FIG. 6(b) is a cross-sectional view showing the focusing of an electron beam from a conventional electron source equipped with a guard electrode, and FIG. 6(c) is a cross-sectional view showing the focusing of an electron beam from a conventional electron source equipped with a guard electrode and having a curved concave surface in the center part.

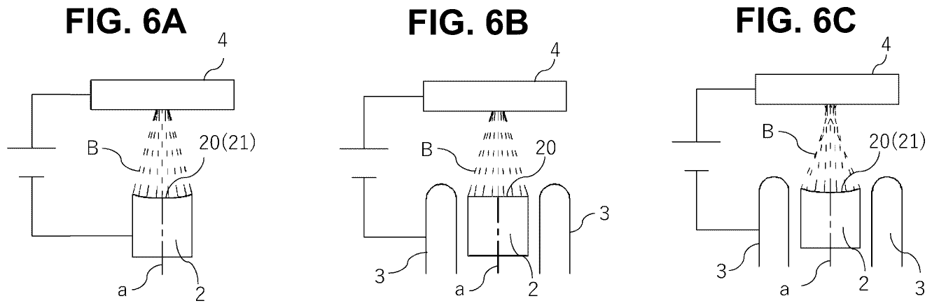

### MODE FOR IMPLEMENTING THE INVENTION

The present invention will be explained below with reference to the drawings.

### Embodiment 1

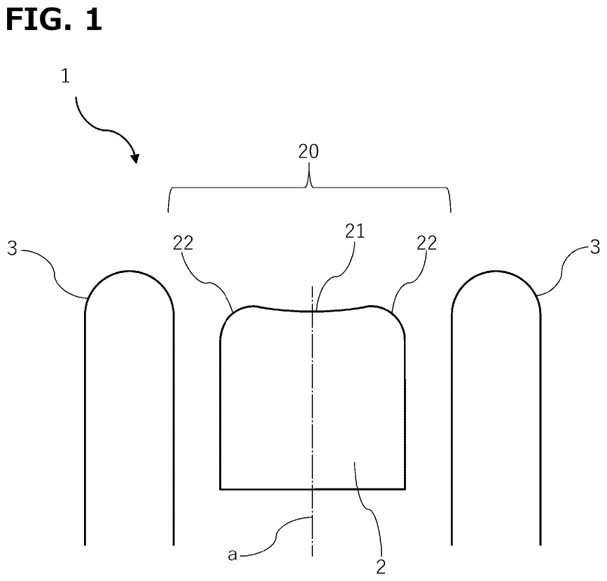

An electron beam emission structure 1 of an embodiment 1, which is one aspect of the present invention shown in FIG. 1, is provided with an electron source 2 and a guard electrode 3.

The electron source 2 functions as an emitter that emits an electron beam B to a target 4 (anode) of a field emission device such as a cold cathode-type X-ray tube. The electron source 2 is made of a well-known material applied for emitters of cold cathode-type X-ray tubes and the like, and is formed in a cylindrical shape. The end surface of the electron source 2 that faces the target 4 constitutes an electron emission surface 20. The center part of the electron emission surface 20 forms a curved concave surface 21, while the peripheral edge portion thereof forms a curved convex surface 22.

The guard electrode 3 is made of a well-known material applied for guard electrodes of cold cathode-type X-ray tubes and the like, and is disposed around the electron source 2.

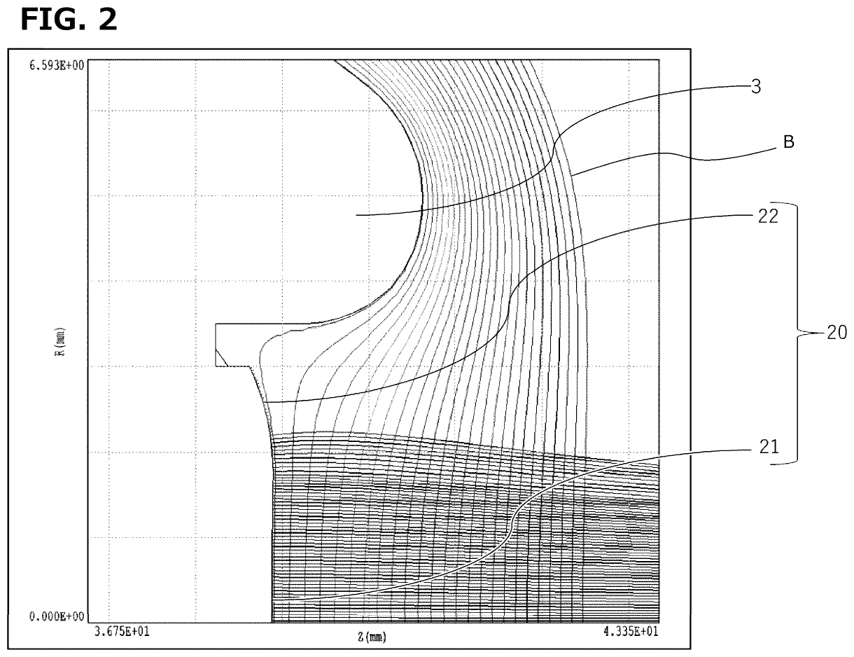

Referring to FIGS. 1 and 2, an example of the operation of the embodiment 1 will be explained.

The electron beam B emitted from the center part of the electron emission surface 20 is irradiated toward the center of the target 4 by the curved concave surface 21 of the center part. Although, at the peripheral edge portion of the electron emission surface 20, the electron beam B is irradiated toward the outer periphery, it is deflected toward the center axis a of the electron source 2 by the electric field formed by the guard electrode 3 and is focused toward the center of the target 4. In the center part of the electron emission surface 20, the electron beam B is focused by the curved concave surface 21, and at the peripheral edge portion of the electron emission surface 20, the electron beam B is focused by the electric field formed by the guard electrode 3, thereby suppressing the electron beam B from being doubly focused.

In addition, by the curved convex surface 22 at the peripheral edge portion, the electric field of the entire peripheral edge portion of the electron emission surface 20 can be reduced, thereby suppressing electric field concentration at the peripheral edge portion and reducing the risk of discharge due to insulation breakdown.

In a conventional technology, it was difficult to focus the electron beam B on the center axis a of the electron source 2.

In contrast, according to the embodiment 1, both the electron beam B emitted from the center part of the electron emission surface 20 of the electron source 2 and the electron beam B emitted from the peripheral edge portion of the electron emission surface 20 can be focused on the center axis a of the electron source 2.

### Embodiment 2

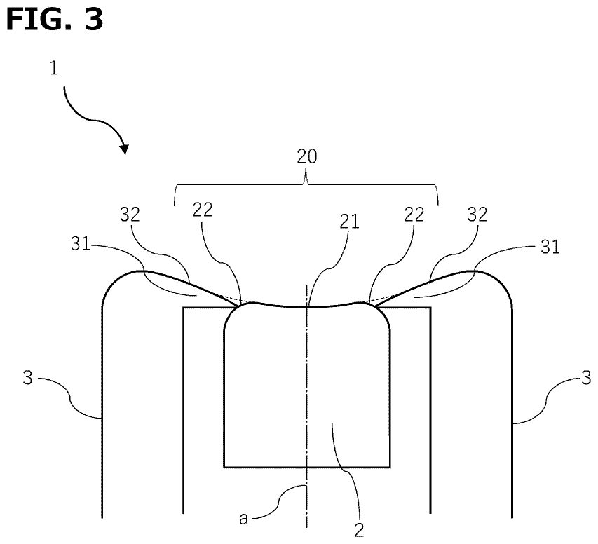

The electron beam emission structure 1 of an embodiment 2, which is one aspect of the present invention shown in FIG. 3, is the same as that of the embodiment 1 except that it is provided with a covering portion 31 covering the peripheral edge portion of the electron emission surface 20 of the electron source 2 at the end portion of the guard electrode 3. The surface of the covering portion 31 has a curved convex surface 32 that is shaped to match the electric field of the curved concave surface 21 of the electron emission surface 20.

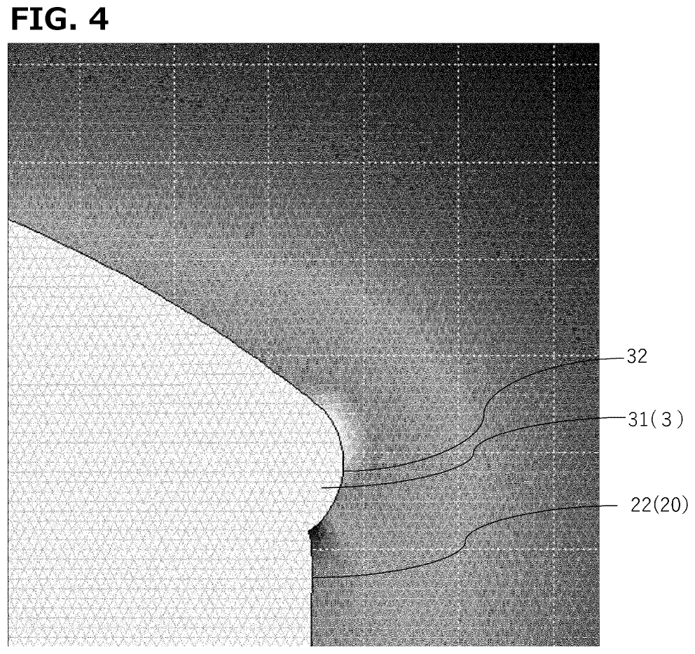

Referring to FIGS. 3 and 4, an example of the operation of the embodiment 2 will be explained.

The electron beam B emitted from the center part of the electron emission surface 20 of the electron source 2 is focused toward the target 4. Although, at the peripheral edge portion of the electron emission surface 20, the electron beam B is irradiated toward the outer periphery, it is deflected toward the center axis a of the electron source 2 by the electric field formed by the guard electrode 3 and is focused toward the target 4, as shown in FIGS. 3 and 4. In addition, the peripheral edge portion of the electron emission surface 20 is covered by the covering portion 31 of the guard electrode 3, making the boundary between the guard electrode 3 and the electron emission surface 20 mechanically smooth, and the electric fields of the guard electrode 3 and the electron emission surface 20 are combined. Consequently, electric field concentration at the peripheral edge portion of the electron emission surface 20 is suppressed, thereby preventing failures caused by unexpected abnormal discharges.

According to the above embodiment 2, as shown in the electric field distribution diagram in FIG. 4, electric field concentration does not physically occur at the peripheral edge portion of the electron emission surface 20, thereby suppressing the occurrence of the electric field concentration at the peripheral edge portion. Therefore, the risk of discharge can be reduced, and a strong electric field can be obtained by the electron source 2, thereby achieving large current.

### Embodiment 3

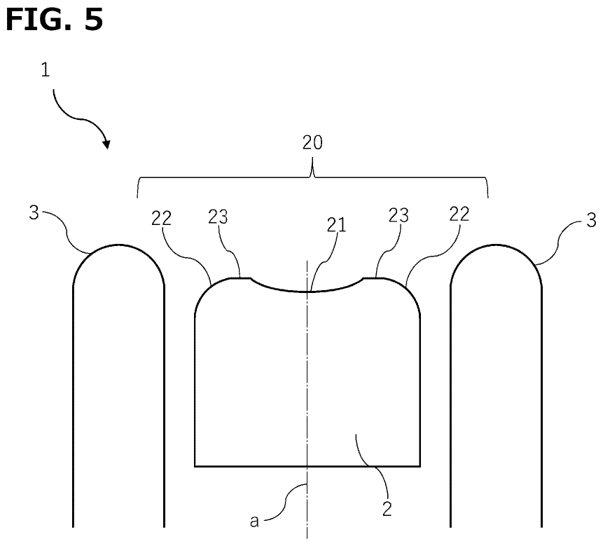

In the electron beam emission structure 1 in an embodiment 3, which is one aspect of the present invention shown in FIG. 5, the boundary between the curved concave surface 21 and the curved convex surface 22 of the electron emission surface 20 has a smooth surface 23. The smooth surface 23 is formed such that the electric fields of the curved concave surface 21 and the curved convex surface 22 are matched. In addition, the smooth surface 23 may have a curved surface.

Referring to FIG. 5, an example of the operation of the embodiment 3 will be explained.

Similar to the embodiment 1, the electron beam B emitted from the center part of the electron emission surface 20 of the electron source 2 is focused toward the target 4. Although, at the peripheral edge portion of the electron emission surface 20, the electron beam B is irradiated toward the outer periphery, it is deflected toward the center axis a of the electron source 2 by the electric field formed by the guard electrode 3 and is focused toward the target 4.

In the embodiment 3, as shown in FIG. 4, unexpected discharge generated at the electron source 2 due to electric field concentration on the guard electrode 3 can also be avoided and reduced. However, when the electric field is concentrated on the guard electrode 3, the focusing ability of the electron beam B of the guard electrode 3 increases. In the center part of the electron emission surface 20, the electron beam B is focused by the large R-shape of the curved concave surface 21. At the peripheral edge region of the electron emission surface 20, the electron beam B is focused by the electric field of the guard electrode 3. The boundary between the curved concave surface 21 and the curved convex surface 22 of the electron emission surface 20 is the point where the focusing characteristic of the electron beam B switches. At this boundary, the smooth surface 23 is ensured so as to match the electric fields of the curved concave surface 21 and the curved convex surface 22 at the above-mentioned switching point, enabling the electron beams B from the curved concave surface 21 and the curved convex surface 22 that are focused in different ways to be mixed.

According to the above embodiment 3, the electron beam B can be focused while the risk of abnormal discharge is assigned on the guard electrode 3. In addition, by providing the smooth surface 23 connecting the curved concave surface 21 and the curved convex surface 22 of the electron emission surface 20, it is possible to mix the electron beam B emitted from the part close to the center part of the electron emission surface 20 with the beam emitted from the part close to the peripheral edge portion of the electron emission surface 20.

1.-4. (canceled)

5. An electron beam emission structure comprising:
an electron source for emitting an electron beam to a target; and
a guard electrode disposed around the electron source so as to be apart from the electron source,
wherein an electron emission surface of the electron source for emitting the electron beam has a center part forming a curved concave surface and a peripheral edge portion forming a curved convex surface, and
wherein an end portion of the guard electrode faces the target at a position closer to the target than to the electron emission surface, and has a curved convex surface.

6. The electron beam emission structure according to claim 5,
wherein the electron emission surface has a smooth surface at a boundary between the curved concave surface and the curved convex surface.

7. A field emission device having the electron beam emission structure according to claim 5.
